(19) United States
(12) Patent Application Publication
(10) Pub. No.: US 2026/0066011 A1
(43) Pub. Date: Mar. 5, 2026

(54) MEMORY DEVICES, OPERATING METHODS THEREOF AND MEMORY SYSTEMS

(71) Applicant: YANGTZE MEMORY TECHNOLOGIES HOLDING CO., LTD., Wuhan (CN)

(72) Inventors: Yuanyuan MIN, Wuhan (CN); Feng XU, Wuhan (CN); Wendong WANG, Wuhan (CN); Lei JIN, Wuhan (CN); ZongLiang HUO, Wuhan (CN)

(21) Appl. No.: 19/291,239

(22) Filed: Aug. 5, 2025

(30) Foreign Application Priority Data
Aug. 29, 2024 (CN) 202411207111X

(51) Int. Cl. G11C 16/30; G11C 16/10; G11C 16/24; G11C 16/26

(52) U.S. Cl. CPC G11C 16/30; G11C 16/102; G11C 16/24; G11C 16/26

(57) ABSTRACT

The examples of the present disclosure disclose a semiconductor device and an operating method thereof and a system. The semiconductor device includes: a plurality of memory string groups each including at least one memory string; and a plurality of bit lines each coupled with a plurality of memory string groups arranged along a first direction; wherein string resistances corresponding to the plurality of memory string groups with which a same selected bit line of the plurality of bit lines is coupled decrease sequentially along a direction from a first end of the selected bit line towards a second end of the selected bit line; and the first end is a node where the selected bit line is coupled with a page buffer or a bit line driver.

### CROSS-REFERENCE TO RELATED APPLICATIONS

The present disclosure claims priority to Chinese Patent Application No. 202411207111X, which was filed Aug. 29, 2024, and is hereby incorporated herein by reference in its entirety.

### TECHNICAL FIELD

Examples of the present disclosure relate to the field of semiconductor technologies, and relate to, but are not limited to, semiconductor devices and an operating methods thereof and systems.

### BACKGROUND

In a classical Von Neumann computing architecture, a memory and a processor are separated, and data transmission is performed between the two through a data bus. When a command is executed, the processor first reads data from the memory, and after processing is completed, the updated data is written back into the memory, so that frequent data migration brings huge power consumption and time overheads. In addition, due to limited memory bandwidth, the processing speed of the processor is limited by the access speed of the memory, and computing performance is greatly affected. With the rise of applications such as big data and artificial intelligence, the processing of massive data makes the bottleneck of Von Neumann computing architecture more and more prominent.

### SUMMARY

According to a first aspect of the present disclosure, a semiconductor device is provided, including: a plurality of memory string groups each including at least one memory string; and a plurality of bit lines each coupled with a plurality of memory string groups arranged along a first direction; wherein string resistances corresponding to a plurality of memory string groups with which a same selected bit line of the plurality of bit lines is coupled decrease sequentially along a direction from a first end of the selected bit line towards a second end of the selected bit line; and the first end is a node where the selected bit line is coupled with a page buffer or a bit line driver.

In some examples, the string resistances corresponding to a plurality of memory string groups with which a same selected bit line of the plurality of bit lines is coupled decrease sequentially along a direction from a first end of the selected bit line towards a second end of the selected bit line includes: along the direction from the first end towards the second end, threshold voltages of top select transistors of the plurality of memory string groups with which the same selected bit line is coupled decrease sequentially.

In some examples, each of the memory string groups includes a plurality of memory strings, and each of the memory strings includes the top select transistor; wherein threshold voltages of the top select transistors of each of the memory strings in a same memory string group are substantially the same

In some examples, each of the memory string groups includes a plurality of memory strings, each of the memory strings includes the top select transistor; wherein along the direction from the first end towards the second end, threshold voltages of the top select transistors of the plurality of memory strings in a same memory string group decrease sequentially.

In some examples, the string resistances corresponding to a plurality of memory string groups with which a same selected bit line of the plurality of bit lines is coupled decrease sequentially along a direction from a first end of the selected bit line towards a second end of the selected bit line includes: along the direction from the first end towards the second end, threshold voltages of dummy transistors of the plurality of memory string groups with which the same selected bit line is coupled decrease sequentially.

In some examples, the string resistances corresponding to a plurality of memory string groups with which a same selected bit line of the plurality of bit lines is coupled decrease sequentially along a direction from a first end of the selected bit line towards a second end of the selected bit line includes: along the direction from the first end towards the second end, numbers of dummy transistors of the plurality of memory string groups with which the same selected bit line is coupled decrease sequentially.

In some examples, each of the memory string groups includes a plurality of memory strings, and each of the memory strings includes dummy transistors; and wherein a number of dummy transistors of each of the memory strings in a same memory string group is the same.

In some examples, each of the memory string groups includes the plurality of memory strings, and each of the memory strings includes dummy transistors; wherein along the direction from the first end towards the second end, numbers of the dummy transistors of the plurality of memory strings in the same memory string group decrease sequentially.

In some examples, the memory string includes at least two sub-memory strings stacked in sequence; wherein the dummy transistor is a transistor at a bottom of the at least one sub-memory string.

In some examples, the memory string includes a plurality of memory cells connected in series; the semiconductor device further includes a plurality of word lines and a peripheral circuit, each of the word lines is coupled with the plurality of memory cells arranged along a second direction, and the second direction intersects with the first direction; the peripheral circuit is coupled with the plurality of memory string groups through the plurality of word lines and the plurality of bit lines, and the peripheral circuit is configured to: apply a read voltage and a pass voltage to a selected word line and an unselected word line of the plurality of word lines, respectively; apply corresponding input voltages to a plurality of top select lines coupled with the plurality of memory string groups, respectively; and sense an electrical signal on the selected bit line; wherein along the direction from the first end towards the second end, string currents corresponding to the plurality of memory string groups with which the same selected bit line is coupled increase sequentially.

In some examples, the semiconductor device includes a plurality of memory blocks each including the plurality of memory string groups.

In some examples, the semiconductor device includes a plurality of memory planes each including a plurality of the memory blocks.

In some examples, the semiconductor device includes a three-dimensional NAND memory.

According to a second aspect of the present disclosure, an operating method of a semiconductor device is provided, including: applying a read voltage and a pass voltage to a selected word line and an unselected word line of a plurality of word lines, respectively; applying corresponding input voltages to a plurality of upper select lines coupled with a plurality of memory string groups, respectively; and sensing an electrical signal on a selected bit line among a plurality of bit lines; wherein each of the bit lines is coupled with a plurality of memory string groups arranged along a first direction; string resistances corresponding to the plurality of memory string groups with which the same selected bit line is coupled decrease sequentially along a direction from a first end of the selected bit line towards a second end of the selected bit line; and the first end is a node where the selected bit line is coupled with a page buffer or a bit line driver.

In some examples, the operating method further includes: performing a program operation on top select transistors of the plurality of memory string groups, so that threshold voltages of the top select transistors of the plurality of memory string groups with which the same selected bit line is coupled decrease sequentially along the direction from the first end towards the second end.

In some examples, in a process of performing the program operation, a program pulse width of the top select transistors of the plurality of memory string groups relatively close to the first end is greater than a program pulse width of the top select transistors of the plurality of memory string groups relatively far away from the first end.

In some examples, in a process of performing the program operation, a program time of the top select transistors of the plurality of memory string groups relatively close to the first end is greater than a program time of the top select transistors of the plurality of memory string groups relatively far away from the first end.

In some examples, the operating method further includes: performing a program operation on dummy transistors of a plurality of memory string groups, so that threshold voltages of the dummy transistors of the plurality of memory string groups with which the same selected bit line is coupled decrease sequentially along the direction from the first end towards the second end.

In some examples, the operating method further includes: applying the pass voltage to a dummy word line coupled with a dummy transistor; wherein along the direction from the first end towards the second end, numbers of dummy transistors of the plurality of memory string groups coupled with the same selected bit line decrease sequentially.

According to a third aspect of the examples of the present disclosure, a system is provided, including: at least one semiconductor device according to any example of the first aspect of the examples of the present disclosure; and a controller coupled with the semiconductor device, wherein the controller is configured to send input data to the semiconductor device and receive a computation result of the semiconductor device.

### BRIEF DESCRIPTION OF THE DRAWINGS

In the drawings, unless otherwise specified, same reference numerals refer to the same or similar components or elements throughout the several figures. These figures are not necessarily drawn to scale. These drawings depict only some implementations according to the present application and should not be considered as limiting the scope of the present application.

FIG. 1 is a schematic diagram of a semiconductor device shown according to an example.

FIG. 2 is a schematic diagram of a memory cell array shown according to an example.

FIG. 3 is a schematic diagram of a three-dimensional NAND memory cell array shown according to an example.

FIG. 4 is a schematic diagram of computing in memory using a three-dimensional NAND memory shown according to an example.

FIG. 5 is a schematic diagram of a bit line being coupled with a plurality of memory strings shown according to an example.

FIG. 6 is a schematic diagram of current distribution on a bit line shown according to an example.

FIG. 7 is a schematic diagram of a semiconductor device shown according to an example of the present disclosure.

FIG. 8 is a schematic diagram of one bit line being coupled with a plurality of memory strings shown according to a first example of the present disclosure.

FIG. 9 is a first schematic diagram of bit line voltage drops according to various examples shown in the present disclosure.

FIG. 10 is a schematic diagram of compensating channel resistances of top select transistors of different memory strings shown according to an example of the present disclosure.

FIG. 11 is a schematic diagram of current distribution on a bit line shown according to an example of the present disclosure.

FIG. 12 is a schematic diagram of one bit line being coupled with a plurality of memory strings shown according to a second example of the present disclosure.

FIG. 13 is a second schematic diagram of bit line voltage drops according to various examples shown in the present disclosure.

FIG. 14 is a flowchart of an operating method of a semiconductor device shown according to an example of the present disclosure.

FIG. 15A is a schematic diagram of a system shown according to the first example of the present disclosure.

FIG. 15B is a schematic diagram of a system shown according to the second example of the present disclosure.

FIG. 16A is a schematic diagram of a memory card having a memory system shown according to an example of the present disclosure.

FIG. 16B is a schematic diagram of a solid state drive having a memory system shown according to an example of the present disclosure.

### DETAILED DESCRIPTION

To facilitate understanding of the present disclosure, examples of the present disclosure will be described in more detail below with reference to related drawings. Although examples of the present disclosure are shown in the drawings, the present disclosure may be implemented in various forms and should not be limited by the specific examples set forth herein. Rather, these implementations are provided to enable a more thorough understanding of the present disclosure, and to fully convey the scope of the present disclosure to those skilled in the art.

In the following description, numerous specific details are given in order to provide a more thorough understanding of the present disclosure. However, it will be apparent to those skilled in the art that the present disclosure may be practiced without one or more of these details. In some examples, in order to avoid confusion with the present disclosure, some technical features known in the art are not described; for example, not all the features of actual examples are described herein, and well-known functions and structures are not described in detail.

In general, the terms may be understood at least in part based on the use in context. For example, the term “one or more” as used herein may be used to describe any feature, structure, or characteristic in a singular sense, or may be used to describe a combination of features, structures, or characteristics in a plural sense, depending at least in part on the context. Similarly, terms such as “a” or “the” may likewise be understood to convey singular usage or convey plural usage, depending at least in part on context. Additionally, the term “based on” may be understood as not necessarily intended to convey an exclusive set of factors, and may instead allow for the presence of additional factors not necessarily explicitly described, again depending at least in part on the context.

Unless otherwise defined, the terms used herein are for the purpose of describing specific examples only and are not for the purpose of limiting the present disclosure. As used herein, the singular forms “a,” “an,” and “the” are also intended to include the plural forms unless the context clearly indicates other forms. It should also be understood that the terms “comprising” and/or “including,” when used in this specification, determine the presence of features, integers, steps, operations, elements and/or components, but do not preclude the presence or addition of one or more other features, integers, steps, operations, elements, components and/or groups. As used herein, the term “and/or” includes any and all combinations of related listed items.

For a thorough understanding of the present disclosure, detailed steps and detailed structures will be proposed in the following description to explain the technical solutions of the present disclosure. Preferred examples of the present disclosure are described in detail below, however, in addition to these detailed descriptions, the present disclosure may have other implementations.

In order to solve the bottleneck of a classical Von Neumann computing architecture, a computing in memory chip architecture emerges, and the basic idea is to embed a computing function in a memory, and directly use the memory to perform logic operations, so that the data transmission amount and the transmission distance between the memory and the processor are reduced, the computing performance is improved while the power consumption is reduced, and therefore a computing system with high computing power, high bandwidth and high energy efficiency is expected to be constructed.

The computing in memory chip has both storage capability and calculation capability by virtue of its own physical characteristics. The storage capability refers to the capability of different memories to store numerical values by changing their conductance values according to their physical characteristics, and the computing capability refers to the capability of completing vector matrix multiplication calculation within a certain time by constructing an array composed of memory devices according to Ohm's law and Kirchhoff's law. The computing in memory chip includes, but is not limited to, a static random access memory (SRAM), a dynamic random access memory (DRAM), and a NAND flash memory. A NAND flash memory is a non-volatile memory with a large capacity, so becomes an object widely concerned in computing in memory chips. Related content of the NAND flash memory will be described below.

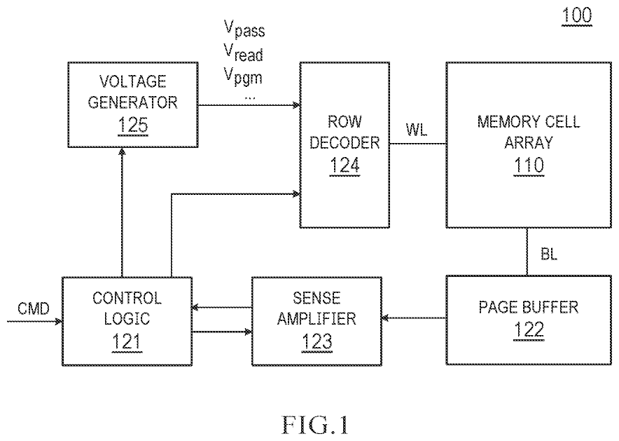

FIG. 1 is a schematic diagram of a semiconductor device including but not limited to a three-dimensional NAND memory shown according to an example, in an example of the present disclosure, the three-dimensional NAND memory will be taken as an example for exemplary illustration.

Referring to FIG. 1, the semiconductor device 100 includes a memory cell array 110 and peripheral circuits coupled with the memory cell array 110. The peripheral circuits may be coupled with memory cell array 110 through bit lines BL, word lines WL, and other drive/select lines (not shown in FIG. 1). The peripheral circuits may include any suitable analog, digital, and mixed-signal circuit for facilitating operations of the memory cell array 110 by applying voltage and/or current signals to each target memory cell and sensing voltage and/or current signals from each target memory cell through the bit lines BL, word lines WL, and other drive/select lines. The memory cell array 110 will be described in detail below, and details are not described here again.

The peripheral circuits may include control logic 121, page buffer 122, sense amplifier 123, row decoder 124, and voltage generator 125. Peripheral circuits may include various types of circuit formed using metal-oxide-semiconductor (MOS) technology. In some examples, additional peripheral circuits not shown in FIG. 1 may also be included.

The page buffer 122 may be configured to read data from the memory cell array 110 and program (also referred to as write) data to the memory cell array 110 according to control signals from the control logic 121. In one example, the page buffer 122 may store one page of program data (write data) to be programmed into one physical page of the memory cell array 110. In another example, the page buffer 122 may perform a program verify operation to ensure that data has been correctly programmed into memory cells coupled with the selected word line. In yet another example, the page buffer 122 may also sense low power signals representing data bits stored in the memory cells from bit lines, and the sense amplifier 123 amplifies a small voltage swing to an identifiable logic level in a read operation. The page buffer 122 and the sense amplifier 123 may be configured to be controlled by the control logic 121.

Row decoder 124 may be configured to be controlled by the control logic 121 and select/deselect memory blocks of the memory cell array 110 and select/deselect the word lines with which the memory blocks are coupled. The row decoder 124 may also be configured to drive the word lines using word line voltages generated from the voltage generator 125. In some examples, the row decoder 124 may also select/deselect and drive the top select lines and the bottom select lines. As described in detail below, the row decoder 124 is configured to perform program operations on the memory cells coupled with the selected word line(s). The voltage generator 125 may be configured to be controlled by the control logic 121 and generate the word line voltages (e.g., program voltage V_{pgm}, read voltage V_{read}, pass voltage Vₚₐₛₛ, etc.) to be supplied to the memory cell array 110, and bit line voltages and source line voltages to be supplied to the memory cell array 110.

The control logic 121 may be coupled with each peripheral circuit described above and configured to control the operation of each peripheral circuit. Registers (not shown) may be coupled with the control logic 121 and include status registers, command registers, and address registers for storing status information, command operation codes, and command addresses for controlling operation of each peripheral circuit. An interface (not shown) may be coupled with the control logic 121 and act as a control buffer to buffer and relay control commands CMD received from a host (not shown) to the control logic 121 and to buffer and relay status information received from the control logic 121 to the host. The interface may also be coupled with a column decoder/a bit line driver via a data bus and act as a data I/O interface and a data buffer to buffer and relay data to the memory cell array 110 or relay or buffer data from the memory cell array 110.

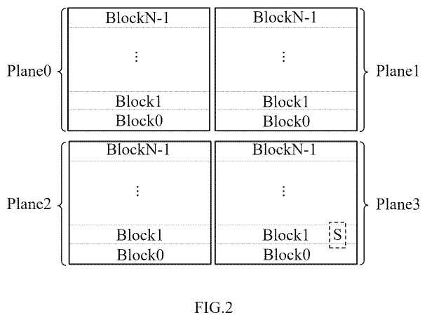

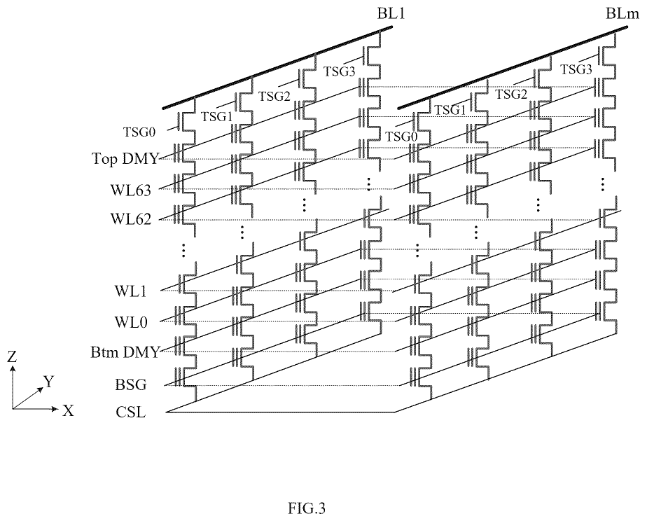

FIG. 2 is a schematic diagram of a memory cell array shown according to an example. Referring to FIG. 2, the memory cell array may include a plurality of memory planes, such as Plane0, Plane1, Plane2 and Plane3. Each of the memory plane includes a plurality of memory blocks, for example, Block0, Block1, . . . , BlockN−1, N is an integer greater than 1. It should be noted that the number of memory planes is not limited to 4 shown in FIG. 2, and may be other numbers, for example, 1, 2, or 8 etc.; and the number of memory blocks included in any two memory planes may be the same or different, which is not limited in this disclosure. The memory cell array may include a three-dimensional NAND memory cell array, and the three-dimensional NAND memory cell array in the S region in FIG. 2 is described below with reference to FIG. 3 as an example.

FIG. 3 is a schematic diagram of a three-dimensional NAND memory cell array shown according to an example. The memory cells are NAND memory cells and are provided in a form of an array of memory strings, and each of the memory strings extends vertically and includes a plurality of memory cells coupled in series and vertically stacked. Each of the memory cells may hold a continuous analog value, e.g., voltage or charge, which is depended on the number of electrons trapped within the region of the memory cell. Each of the memory cells may be a floating gate type of memory cell including a floating gate transistor, or a charge trapping type of memory cell including a charge trapping transistor. For example, referring to FIG. 3, each of the memory strings includes 64 memory cells coupled in series and vertically stacked, 64 word lines are respectively coupled with the respective memory cells and are respectively represented as WL0, WL1, . . . , WL62, and WL63 in FIG. 3. In practical applications, the number of memory cells and the number of word lines are not limited to those shown in FIG. 3, and may be other numbers.

In some examples, each of the memory cells is a Single Level Cell (SLC) having two possible memory states and thus can store one bit of data. For example, a first memory state “0” may correspond to a first voltage range and a second memory state “1” may correspond to a second voltage range. In some examples, each of the memory cells is a multi-level cell capable of storing more than a single bit of data in four or more memory states, e.g., a multi-level cell (MLC) storing two bits per cell, a triple level cell (TLC) storing three bits per cell, or a quad-level cell (QLC) storing four bits per cell.

In some examples, each of the memory strings may include a bottom select transistor (BSG) at its source terminal and a top select transistor (TSG) at its drain terminal. The bottom select transistor and the top select transistor may be configured to activate a selected memory string during read and program operations. The sources of the memory strings in a same memory block may be coupled with each other through a common source line (CSL). In other words, all memory strings in the same memory block have an array common source (ACS).

In some examples, the top select transistor of each of the memory strings is coupled with respective bit line from which data may be read or written via an output bus (not shown). For example, as shown in FIG. 3, the memory cell array may be coupled with the peripheral circuits through m bit lines, wherein the m bit lines are BL0, BLm−1, and m is an integer greater than 1. Each of the bit lines is coupled with a plurality of memory strings arranged along a bit line extension direction. For example, FIG. 3 shows that 4 memory strings arranged along the bit line extension direction are coupled with the same bit line, and the top select transistors of the 4 memory strings are TSG0, TSG1, TSG2, and TSG3, respectively. In practical applications, the number of memory strings coupled with each of the bit lines is not limited to that shown in FIG. 3, and may be other numbers.

In some examples, each of the memory strings is configured to be selected or deselected by applying a select voltage (e.g., a voltage above a threshold voltage of the top select transistor) or a deselect voltage (e.g., 0V) to the corresponding top select transistor through one or more top select lines and/or by applying a select voltage (e.g., a voltage above a threshold voltage of the bottom select transistor) or a deselect voltage (e.g., 0V) to the corresponding bottom select transistor through one or more bottom select lines.

In some examples, each of the memory strings may include a bottom dummy transistor between bottom memory cell of the memory string and the bottom select transistor and a top dummy transistor between top memory cell of the memory string and the top select transistor. The bottom dummy transistor of each of the memory strings is coupled with a corresponding bottom dummy word line Btm DMY, and the top dummy transistor of each of the memory strings is coupled with a corresponding top dummy word line Top DMY. In practical applications, the number of the bottom dummy transistors and the top dummy transistors in each of the memory strings is not limited to that shown in FIG. 3, and may be other numbers.

It should be noted that the memory string may be organized into a plurality of memory blocks shown in FIG. 2, and each of the plurality of memory blocks may have a common source line. In some examples, each of the memory blocks is a basic unit of data for an erase operation, e.g., all memory cells on the same memory block are erased simultaneously. To erase memory cells in a selected memory block, common source lines coupled with the selected memory block and unselected memory blocks on the same plane as the selected memory block may be biased with an erase voltage. It should be appreciated that in some examples, the erase operation may be performed at a half memory block level, at a quarter memory block level, or at a level having any suitable number of memory blocks or any suitable fraction of memory block. The memory cells of adjacent memory strings may be coupled by the word lines that select which row of the memory cells is affected by read and program operations.

In combination with FIG. 1, when a three-dimensional NAND memory is used to perform an computation, the control logic 121 may receive input data sent by the controller, a digital-to-analog conversion circuit (not shown in FIG. 1) converts the input data into a voltage signal to be applied to a word line or a bit line, the voltage generator 125 generates a corresponding voltage to be applied to the word line or the bit line, the row decoder 124 is configured to drive a selected word line using a word line voltage generated from the voltage generator 125, or a column decoder (not shown in FIG. 1) is configured to drive a selected bit line using a bit line voltage generated from the voltage generator 125. The analog computation result obtained after the computation is transmitted to the analog-to-digital conversion circuit through the page buffer 122 and the column decoder, and the analog-to-digital conversion circuit converts the analog computation result into a digital computation result and transmits the final digital computation result to the control logic 121.

For a computing in memory chip, a product computation or a product accumulation computation between input data and a weight matrix needs to be implemented, the input data may be an input vector or an input matrix composed of a plurality of elements, the weight matrix is composed of a plurality of weights, and each element in the input data needs to be multiplied and accumulated with the plurality of weights in the weight matrix to obtain the corresponding element in the output data.

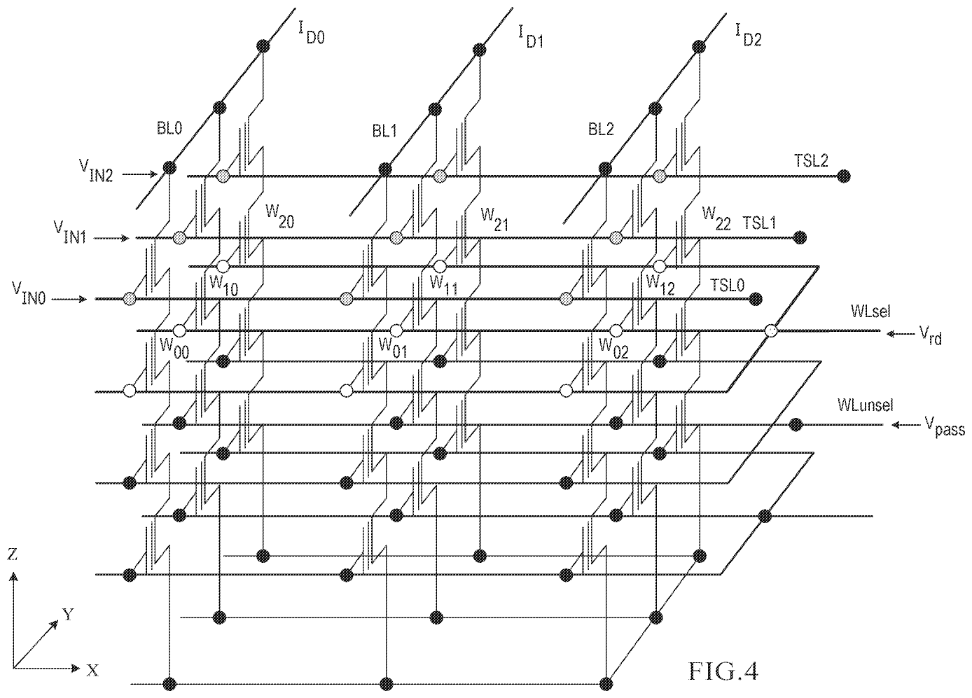

To implement the above computation function, the memory cell array of the three-dimensional NAND memory may be configured to store a weight matrix. Specifically, before the computation starts, weights in the weight matrix may be written into the memory cell array according to a certain mapping rule, and each of the memory cells in the memory cell array may be configured to store one weight. When performing the computation, the semiconductor device may receive input data from the controller, the input data may be an input vector or an input matrix composed of a plurality of elements, and each element in the input data may be converted into an input voltage through the digital-to-analog conversion circuit and input into the memory cell array through the top select lines, and the computation using the three-dimensional NAND memory will be described below with reference to FIG. 4.

FIG. 4 is a schematic diagram of computing in memory using a three-dimensional NAND memory shown according to an example. Referring to FIG. 4, before the computation starts, a plurality of weights (e.g., weights w00 to w22) in the weight matrix are respectively written into a plurality of memory cells coupled with the selected word line WLsel. When the computation is performed, the input voltage obtained by converting the input data is applied to the corresponding top select line (for example, the input voltages V_{IN0}, V_{IN1}, V_{IN2} are respectively applied to the top select lines TSL0, TSL1, TSL2), and the read voltage V_{rd} is applied to the selected word line WLsel and the pass voltage Vₚₐₛₛ is applied to the unselected word line WLunsel; and a computation result can be obtained by sensing the current on the bit line and converting the current on the bit line. Taking the bit line BL0 as an example, the current I_{D0} on the bit line BL0 corresponds to the result of accumulating the product of multiplying the element corresponding to the input voltage V_{IN0} by the weight w₀₀, the product of multiplying the element corresponding to the input voltage V_{IN1} by the weight w₁₀, and the product of multiplying the element corresponding to the input voltage V_{IN2} by the weight w₂₀. The current I_{D1} on bit line the BL1 and the current I_{D2} on the bit line BL2 can be understood with reference to the current I_{D0} on the bit line BL0.

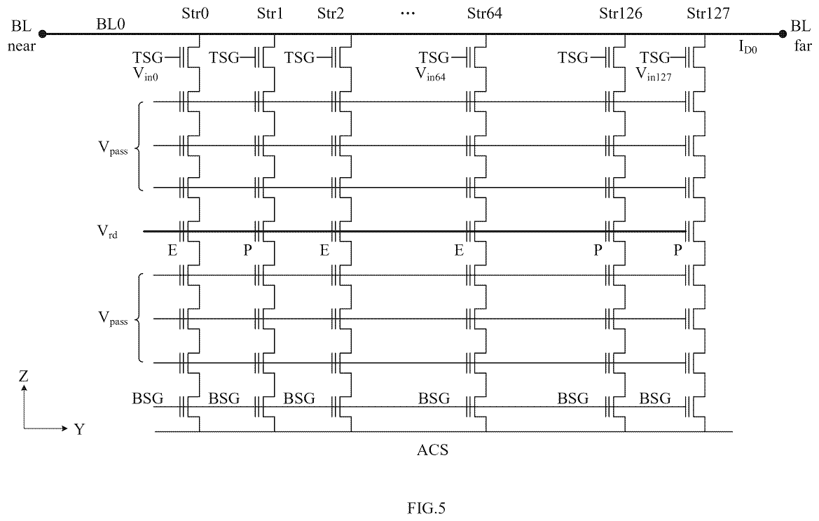

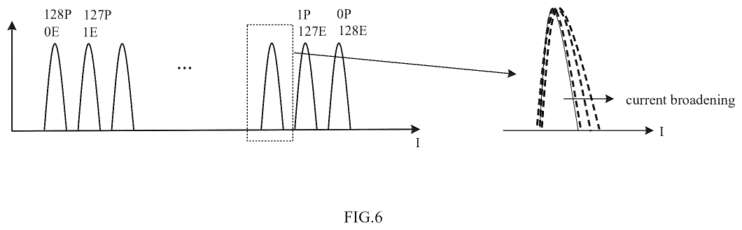

In the NAND computing in memory chip shown in FIG. 4, weights are stored in the memory cells, input voltages corresponding to the input data are input through the top select lines, the bit line outputs a corresponding current, and because a current corresponding to an erased state and a current corresponding to a programmed state of the memory cell are significantly different, the final addition computation is performed through Kirchhoff's law using the current on the bit line. The addition computation of the current on the bit line is usually implemented by calculating a plurality of memory strings coupled with the same bit line in parallel, and in order to further improve the computing power of the chip, the number of parallel memory strings on the same bit line is multiplied, therefore the problem of current broadening on the bit line caused by the difference of bit line voltage drops (BL IR Drop) between the different memory strings on the same bit line needs to be considered, which is further explained below with reference to FIG. 5 and FIG. 6.

FIG. 5 is a schematic diagram of one bit line being coupled with a plurality of memory strings shown according to an example, and FIG. 6 is a schematic diagram of current distribution on the bit line shown according to an example. For ease of understanding, the BL0 is coupled with 128 memory strings Str0 to Str127 will be taken as an example for illustration below, and other bit lines and memory strings coupled thereto may be understood with reference to FIG. 3 and FIG. 5.

Referring to FIG. 5, a part of the 128 memory cells coupled with the selected word line are in a first memory state (an erased state E), and the other part of the memory cells are in a second memory state (a programmed state P). When a computation is performed, the input voltages Vino to Vᵢₙ₁₂₇ are respectively applied to 128 top select lines, a read voltage V_{rd} is applied to a selected word line, and a pass voltage Vₚₐₛₛ is applied to the unselected word lines; the current I_{D0} on the bit line BL0 is sensed and converted, so that a result of accumulating the 128 products of multiplying 128 elements corresponding to the input voltages Vᵢₙ₀ to Vi₁₁₂₇ by corresponding weights is obtained. Here, the input voltages corresponding to the high level “1” in the input voltages Vᵢₙ₀ to Vᵢₙ₁₂₇ may cause the top select transistor TSG coupled with the corresponding top select line to be turned on, and the input voltages corresponding to the low level “0” in the input voltages Vᵢₙ₀ to Vᵢₙ₁₂₇ may cause the top select transistor TSG coupled with the corresponding top select line to be turned off.

In the scheme shown in FIG. 5, the threshold voltages of the top select transistors TSG of the memory strings Str0 to Str127 coupled with BL0 are substantially the same, and the memory string at a near end of the bit line and the memory string at a far end of the bit line are affected differently by the bit line voltage drop. Specifically, from the near end of the bit line towards the far end of the bit line, the bit line voltage drops of the plurality of memory strings gradually increase, for example, the bit line voltage drops of the memory strings Str0 to Str127 satisfy the following rule: str0<str1<str2< . . . <str126<str127, which makes the bit line valid voltages corresponding to the memory strings Str0 to Str127 to be different and causes the current output on BL0 to be broadened, affecting the accuracy of the computing in memory. Here, BL near and BL far in FIG. 5 respectively represent the near end of the bit line and the far end of the bit line.

Taking 128 memory strings being read in parallel as an example, if the bit line BL0 is coupled with 128 memory strings, there may be 129 current distribution patterns, which are respectively represented as 128P0E, 127P1E, . . . , 1P127E, and 0P128E in FIG. 6. For example, for the current distribution pattern of 50P78E corresponding to the current I_{D0}, if the positions of the memory strings in which the 78 E states are located are different, the influence of the bit line voltage drop is different, and the current under the same current distribution pattern is different, resulting in current broadening, as shown in the enlarged view corresponding to the dashed box in FIG. 6. Here, 50P78E indicates that 50 memory cells among the 128 memory cells coupled with the selected word line are in the programmed state P, and 78 memory cells are in the erased state E.

In addition, one bit line outputs one bit line current, and one physical page with a size of 16 KB outputs 16 KB bit line currents in total, and due to the influence of the bit line voltage drop, the 16 KB bit line currents have current broadening with varying degrees. It should be noted that the size of a physical page is not limited to 16 KB, and may also be 2 KB, 4 KB, 8 KB, 32 KB, or the like.

Based on one or more of the foregoing technical problems, an example of the present disclosure provides a semiconductor device. The semiconductor device includes a plurality of memory string groups and a plurality of bit lines; each of the memory string groups includes at least one memory string, and each of the bit lines is coupled with a plurality of memory string groups arranged in the first direction; wherein string resistances corresponding to a plurality of memory string groups with which a same selected bit line of the plurality of bit lines is coupled decrease sequentially along a direction from a first end of the selected bit line towards a second end of the selected bit line; and the first end is a node where the selected bit line is coupled with a page buffer or a bit line driver. In this way, the difference of bit line voltage drops between the memory strings in a plurality of memory string groups with which the same bit line is coupled can be compensated, thereby narrowing the current distribution on the bit line and improving the storage accuracy.

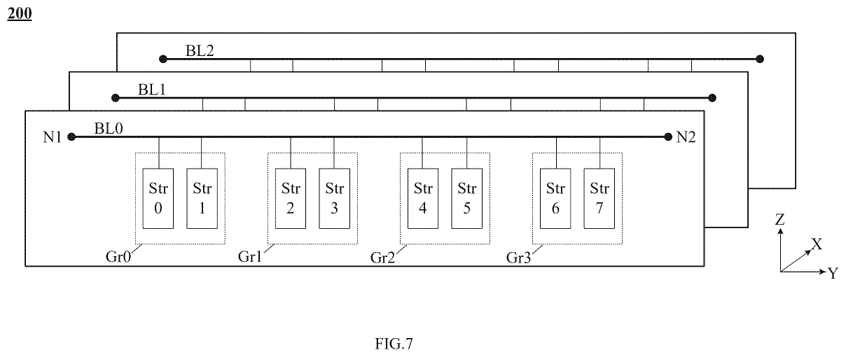

FIG. 7 is a schematic diagram of a semiconductor device shown according to an example of the present disclosure, the semiconductor device includes but is not limited to a three-dimensional NAND memory, and the three-dimensional NAND memory is taken as an example for description in an example of the present disclosure.

Referring to FIG. 7, the semiconductor device includes a plurality of bit lines, such as BL0, BL1 and BL2. Each of the bit lines is coupled with a plurality of memory string groups arranged along the Y direction, for example, memory string group Gr0, memory string group Gr1, memory string group Gr2, and memory string group Gr3. Each of the memory string groups includes at least one memory string, for example, the memory string group Gr0 includes a memory string Str0 and a memory string Str1, the memory string group Gr1 includes a memory string Str2 and a memory string Str3, the memory string group Gr2 includes a memory string Str4 and a memory string Str5, and the memory string group Gr3 includes a memory string Str6 and a memory string Str7.

It should be noted that the number of bit lines in the semiconductor device, the number of memory string groups with which each of the bit lines is coupled, and the number of memory strings in each of the memory string groups are not limited to those shown in FIG. 7, and may also be other numbers. In addition, the number of memory strings in different memory string groups may be the same or different, which is not particularly limited in the present disclosure. The first direction and the second direction used in this example and the following are respectively represented in the figures as a Y direction, an X direction, wherein the Y direction and the X direction intersect and are both perpendicular to the Z direction in the figures, wherein the Y direction is an extending direction of each of the bit lines, the X direction is a direction in which a plurality of bit lines are arranged, and the Z direction is an extending direction of each of the memory strings.

Still referring to FIG. 7, string resistances corresponding to a plurality of memory string groups with which a same selected bit line of the plurality of bit lines is coupled decrease sequentially along a direction from a first end of the selected bit line towards a second end of the selected bit line. The first end used in the present disclosure is the node where the selected bit line is coupled with a page buffer or a bit line driver, e.g., the first end is the near end of the bit line and the second end is the far end of the bit line. In this way, a difference of bit line voltage drops between the memory strings in a plurality of memory string groups with which the same bit line is coupled can be compensated, thereby narrowing the current distribution on the bit line and improving the storage accuracy. Here, the page buffer or the bit line driver may be coupled with one of the two end of the selected bit line that is relatively far away from the memory cell array, or may be coupled with any intermediate node between the two ends of the selected bit line.

Taking the selected bit line is BL0 as an example, along a direction from the first end N1 of BL0 to the second end N2 of BL0, string resistances corresponding to the memory string group Gr0, the memory string group Gr1, the memory string group Gr2, and the memory string group Gr3 with which BL0 is coupled decrease sequentially, for example, string resistances corresponding to memory strings in the memory string group Gr0>string resistances corresponding to memory strings in the memory string group Gr1>string resistances corresponding to memory strings in the memory string group Gr2>string resistances corresponding to memory strings in the memory string group Gr3.

It should be noted that, when the memory string group includes a plurality of memory strings, string resistances corresponding to the plurality of memory strings in the same memory string group may be substantially the same; or string resistances corresponding to the plurality of memory strings in the same memory string group decrease sequentially in a direction from the first end towards the second end. Here, there are two cases where the string resistance is substantially the same: the first case is that string resistances corresponding to the plurality of memory strings are completely the same; and the second case is that string resistances corresponding to a plurality of memory strings have a deviation that is within an allowable first error range, and the first error range may be designed according to a tolerance of an actual semiconductor device.

The string resistance used in this example and hereinafter represents the sum of the resistances of a plurality of transistors in each of the memory strings between a selected bit line and a selected word line. Here, the plurality of transistors between the selected bit line and the selected word line include at least one memory cell transistor and at least one top select transistor; further, when a dummy transistor is disposed in the memory string, the plurality of transistors between the selected bit line and the selected word line may further include at least one dummy transistor.

In some examples, string resistances corresponding to a plurality of memory string groups with which a same bit line is coupled decrease sequentially along a direction from a first end of the bit line towards a second end of the bit line, which is not limited to a selected bit line, and string resistances corresponding to a plurality of memory string groups with which other bit lines are coupled may also adopt the same rule. In some examples, string resistors corresponding to a plurality of memory string groups with which each of the bit lines is coupled decrease sequentially along a direction from a first end of the corresponding bit line towards a second end of the corresponding bit line. In some examples, a plurality of memory string groups or a plurality of memory strings with which each of the bit lines is coupled may be set in a manner described below.

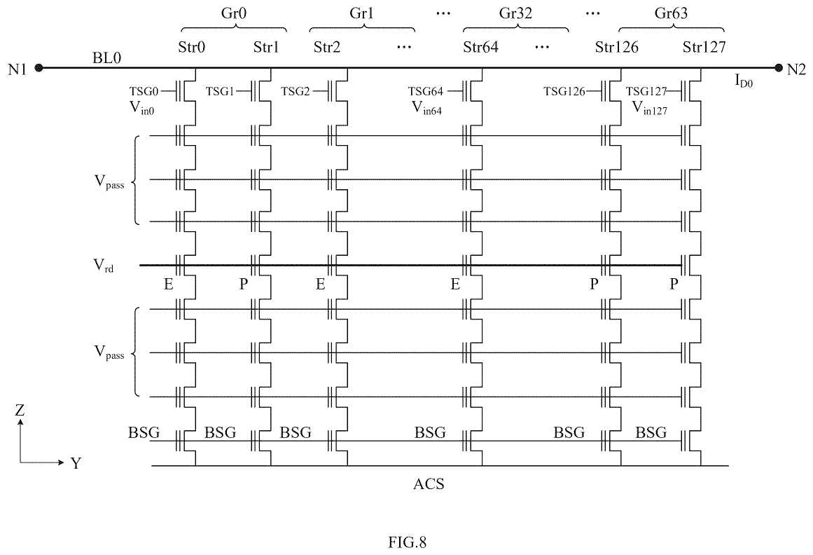

FIG. 8 is a schematic diagram of one bit line being coupled with a plurality of memory strings shown according to a first example of the present disclosure. For ease of understanding, the selected bit line is BL0 which is coupled with 64 memory string groups each including 2 memory strings will be taken as an example below for illustration.

Referring to FIG. 8, the selected bit line BL0 is coupled with 64 memory string groups, e.g., memory string group Gr0, memory string group Gr1, . . . , memory string group Gr32, . . . , memory string group Gr63. Each of the memory string groups includes 2 memory strings, for example, the memory string group Gr0 includes memory string Str0 and memory string Str1, . . . , the memory string group Gr63 includes memory string Str126 and memory string Str127. In practical applications, the number of memory string groups with which each of the bit lines is coupled and the number of memory strings in each of the memory string groups are not limited to those shown in FIG. 8, and may also be other numbers. The number of memory strings in different memory string groups may be the same or different, which is not particularly limited in the present disclosure.

In some examples, string resistances corresponding to a plurality of memory string groups with which a same selected bit line of the plurality of bit lines is coupled decrease sequentially along a direction from a first end of the selected bit line towards a second end of the selected bit line includes: threshold voltages of top select transistors of the plurality of memory string groups with which the same selected bit line is coupled decrease sequentially along the direction from the first end towards the second end.

For example, referring to FIG. 8, in a direction from the first end N1 towards the second end N2, the threshold voltages of the top select transistors of the memory string group Gr0, the memory string group Gr1, . . . , the memory string group Gr32, . . . , and the memory string group Gr63 with which the BL0 is coupled decrease sequentially, for example, the threshold voltage of the top select transistor of the memory string in the memory string group Gr0>the threshold voltage of the top select transistor of the memory string in the memory string group Gr1>, . . . , >the threshold voltage of the top select transistor of the memory string in the memory string group Gr32>, . . . , >the threshold voltage of the top select transistor of the memory string in the memory string group Gr63, so that string resistances corresponding to the memory string group Gr0, the memory string group Gr1, . . . , the memory string group Gr32, . . . , and the memory string group Gr63 decrease sequentially.

It can be understood that, in an example of the present disclosure, by setting different threshold voltages of the top select transistors of the memory strings in different memory string groups, a difference of bit line voltage drops of the different memory strings can be compensated. Specifically, if the closer to the first end, the smaller the bit line voltage drop of a memory string within a memory string group is, the closer to the first end, the higher the threshold voltage of the top select transistor of a memory string within a memory string group is, for example, the memory string group Gr0; if the closer to the second end, the bigger the bit line voltage drop of a memory string within a memory string group is, the closer to the second end, the lower the threshold voltage of the top select transistor of a memory string within a memory string group is, for example, the memory string group Gr32.

In some examples, each of the memory string groups includes a plurality of memory strings, and each of the memory strings includes a top select transistor; wherein the threshold voltages of the top select transistors of each of the memory strings in the same memory string group are substantially the same. Here, there are two cases where the threshold voltages are substantially the same: the first case is that the threshold voltages of the top select transistors of each of the memory strings in the same memory string group are completely the same; and the second case is that threshold voltages of the top select transistors of each of the memory strings in the same memory string group have a deviation that is within an allowable second error range, and the second error range may be designed according to a tolerance of an actual semiconductor device

For example, referring to FIG. 8, within the memory string group Gr0, the threshold voltage Vt_{tsg0} of the top select transistor TSG0 of the memory string Str0 and the threshold voltage Vt_{tsg1} of the top select transistor TSG1 of the memory string Str1 are substantially the same; and the threshold voltage Vt_{tsg1} of the top select transistor TSG1 is greater than the threshold voltage Vt_{tsg2} of the top select transistor TSG2. Within the memory string group Gr63, the threshold voltage Vt_{tsg126} of the top select transistor TSG126 of the memory string Str126 and the threshold voltage Vt_{tsgl27} of the top select transistor TSG127 of the memory string Str127 are substantially the same; and the threshold voltage Vt_{tsg125} of the top select transistor TSG125 is greater than the threshold voltage Vt_{tsg126} of the top select transistor TSG126.

It can be understood that in an example of the present disclosure, a plurality of memory strings coupled with a same selected bit line are divided into a plurality of memory string groups, and the threshold voltages of the top select transistors of each of the memory strings within the same memory string group are substantially the same, so that reasonable compensation may be performed according to the degrees of bit line voltage drop of the plurality of memory strings. For example, the memory strings with substantially the same degrees of the bit line voltage drop are grouped into one group, and the threshold voltages of the top select transistors of the memory strings that are grouped into one group are substantially the same. Here, the grouping manner of the plurality of memory strings is not limited to that shown in FIG. 8.

In some other examples, each of the memory string groups includes a plurality of memory strings, and each of the memory strings includes a top select transistor; and in a direction from the first end towards the second end, the threshold voltages of the top select transistors of the plurality of memory strings within a same memory string group decrease sequentially.

For example, referring to FIG. 8, within the memory string group Gr0, the threshold voltage Vt_{tsg0} of the top select transistor TSG0 of the memory string Str0 is greater than the threshold voltage Vt_{tsg1} of the top select transistor TSG1 of the memory string Str1. Within the memory string group Gr63, the threshold voltage Vt_{tsg126} of the top select transistor TSG126 of the memory string Str126 is greater than the threshold voltage Vt_{tsgl27} of the top select transistor TSG127 of the memory string Str127. For example, in this example, the threshold voltages of the top select transistors of the 128 memory strings Str0 to Str127 coupled with BL0 satisfy the following rule: Vt_{tsg127}<Vt_{tsg126}< . . . <Vt_{tsg2}<Vt_{tsg1}<Vt_{tsg0}.

It can be understood that, in an example of the present disclosure, along the direction from the first end towards the second end, the threshold voltages of the top select transistors of the plurality of memory strings coupled with the same selected bit line decrease sequentially, so as to compensate for differences in bit line voltage drops of different memory strings. Specifically, if the closer to the first end, the smaller the bit line voltage drop of the memory string is, the closer to the first end, the higher the threshold voltage of the top select transistor of the memory string is, for example, the top select transistor TSG0; if the closer to the second end, the bigger the bit line voltage drop of the memory string is, the closer to the second end, the lower the threshold voltage of the top select transistor of the memory string is, for example, the top select transistor TSG127.

In some examples, each of the bit lines is coupled with at least two memory strings of a plurality of memory strings; wherein along a direction from a first end of a selected bit line of a plurality of bit lines to a second end of the selected bit line, among a first memory string and a second memory string with which the same selected bit line is coupled, the string resistance of the first memory string is greater than the string resistance of the second memory string, the first end is a node where the selected bit line coupled with a page buffer or a bit line driver, and the first memory string is closer to the first end than the second memory string. The specific structure of the memory string and the arrangement manner of the plurality of memory strings, the first end of the selected bit line and the second end of the selected bit line, and the string resistance, may be referred to the related descriptions in the foregoing examples and the corresponding figures, and details are not described herein again. The first memory string and the second memory string will be described in detail below.

For example, in combination with FIG. 8, the selected bit line BL0 is coupled with 128 memory strings Str0 to Str127, and the first memory string may be any one of the memory strings Str0 to Str126. For example, the first memory string is the memory string Str0, and the second memory string may be any one of the memory strings Str1 to Str127. For another example, the first memory string is the memory string Str1, and the second memory string may be any one of the memory strings Str2 to Str127. It may be understood that when the first memory string is the memory string Str126, the second memory string may be the memory string Str127. Here, the first memory string may represent a memory string relatively close to the first end among the plurality of memory strings with which the same selected bit line is coupled, and the second memory string may represent a memory string relatively close to the second end among the plurality of memory strings with which the same selected bit line is coupled.

In an example of the present disclosure, among the first memory string and the second memory string coupled with the same selected bit line, by setting the string resistance of the first memory string, which is closer to the first end than the second memory string, to be greater than that of the second memory string, a difference of bit line voltage drops between the first memory string and the second memory string coupled with the same bit line can be compensated, thus the current distribution on the bit line is narrowed, and the accuracy of computing in memory is improved.

In some examples, along the direction from the first end of the selected bit line towards the second end of the selected bit line, among the first memory string and the second memory string coupled with the same selected bit line of the plurality of bit lines, the string resistance of the first memory string is greater than the string resistance of the second memory string, includes: along the direction from the first end towards the second end, among the first memory string and the second memory string coupled with the same selected bit line, the threshold voltage of the top select transistor of the first memory string is greater than the threshold voltage of the top select transistor of the second memory string. In this way, the string resistance of the first memory string may be greater than the string resistance of the second memory string.

In some examples, a plurality of memory strings constitute a plurality of memory string groups, and each of the bit lines is coupled with at least two of the plurality of memory string groups; wherein the first memory string and the second memory string are respectively located in different memory string groups with which the selected bit line is coupled.

For example, in combination with FIG. 8, the selected bit line BL0 is coupled with the memory string groups Gr0 to Gr63, and the first memory string may be located in any one of the memory string groups Gr0 to Gr62. For example, the first memory string is located in the memory string group Gr0, and the second memory string may be located in any one of the memory string groups Gr1 to Gr63. For another example, the first memory string is located in the memory string group Gr1, and the second memory string may be located in any one of the memory string groups Gr2 to Gr63. It may be understood that when the first memory string is located in the memory string group Gr62, the second memory string may be located in the memory string group Gr63.

In some examples, a plurality of memory strings constitute a plurality of memory string groups, and each of the bit lines is coupled with at least two of the plurality of memory string groups; wherein the first memory string and the second memory string are located in a same memory string group coupled with the selected bit line.

For example, in combination with FIG. 8, the selected bit line BL0 is coupled with the memory string groups Gr0 to Gr63, and the first memory string and the second memory string may be located in any one of the memory string groups Gr0 to Gr62. For example, the first memory string and the second memory string are both located in the memory string group Gr0, the first memory string is closer to the first end N1 than the second memory string, the first memory string may be Str0 in FIG. 8, and the second memory string may be Str1 in FIG. 8.

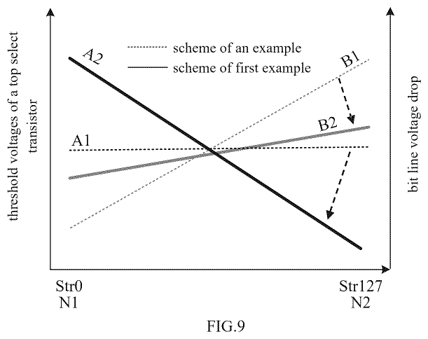

FIG. 9 is a first schematic diagram of the bit line voltage drops according to various examples shown in the present disclosure. A dotted line in FIG. 9 represents an example, wherein the dotted line A1 represents that the threshold voltages of the top select transistors of the 128 memory strings Str0 to Str127 coupled with the same selected bit line are substantially the same, and the dotted line B1 represents the change rule of the bit line voltage drops of the 128 memory strings coupled with the same selected bit line; a solid line in FIG. 9 represents the first example, wherein the solid line A2 represents that the threshold voltages of the top select transistors of the 128 memory strings Str0 to Str127 coupled with the same selected bit line decrease sequentially, and the solid line B2 represents the change rule of the bit line voltage drop of the 128 memory strings coupled with the same selected bit line. It can be seen from FIG. 9 that, by setting the threshold voltages of the top select transistors of the 128 memory strings Str0 to Str127 coupled with the same selected bit line to reduce sequentially, a difference of the bit line voltage drops of different memory strings can be compensated, as shown by dotted line B1 to solid line B2 in FIG. 9. Here, the details about the examples may be referred to the examples related to FIG. 5, and the details about the first example may be referred to the examples related to FIG. 8, which is not repeated for brevity.

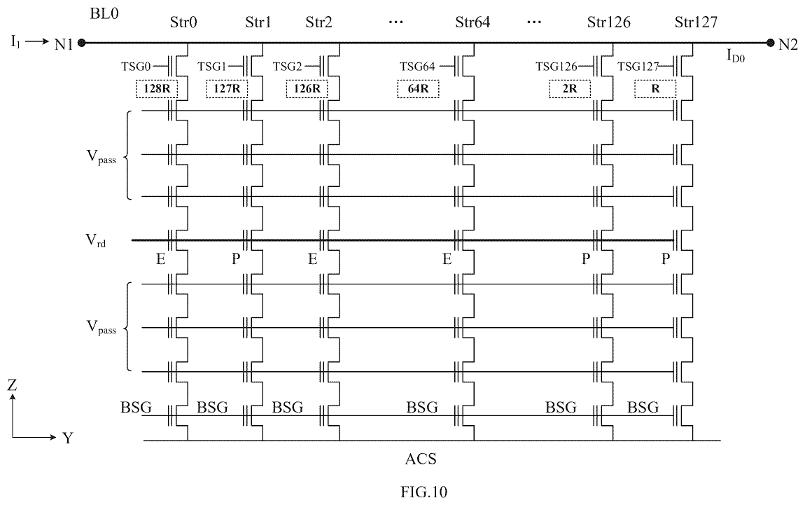

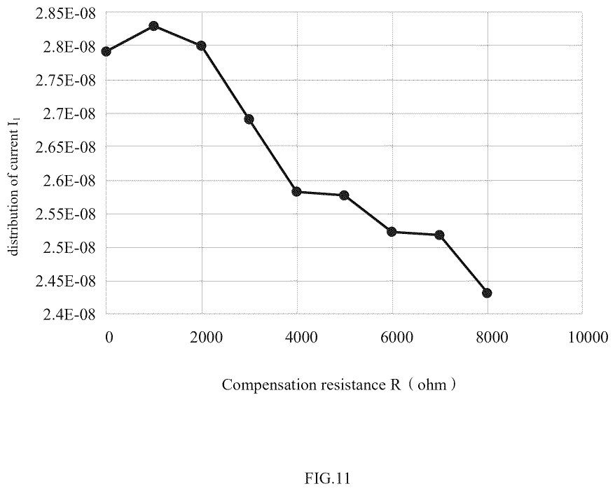

FIG. 10 is a schematic diagram of compensating channel resistances of the top select transistors of different memory strings shown according to an example of the present disclosure, and FIG. 11 is a schematic diagram of current distribution on a bit line shown according to an example of the present disclosure. Referring to FIG. 10, along the direction from the first end N1 towards the second end N2, the channel resistances of the top select transistors of the memory strings Str0 to Str127 decrease sequentially, for example, from 128R to R, so that the distribution of the current I₁ on the bit line BL0 can be narrowed; as shown in FIG. 11, thereby reducing the influence of bit lit voltage drop to the current distribution. It can be understood that, in FIG. 10, the threshold voltages of the top select transistors is simulated by adjusting the channel resistances of the top select transistors to compensate for the difference in the bit line voltage drops.

In some examples, the string resistances corresponding to a plurality of memory string groups with which a same selected bit line of the plurality of bit lines is coupled decrease sequentially along a direction from a first end of the selected bit line towards a second end of the selected bit line includes: along the direction from the first end towards the second end, the threshold voltages of the dummy transistors of the plurality of memory string groups with which the same selected bit line is coupled decrease sequentially.

For example, in combination with FIG. 8, along the direction from the first end N1 to the second end N2, the threshold voltages of the dummy transistors of the memory string group Gr0, the memory string group Gr1, . . . , the memory string group Gr32, . . . , and the memory string group Gr63 with which the BL0 is coupled decrease sequentially, for example, the threshold voltage of the dummy transistor of a memory string in the memory string group Gr0>, . . . , >the threshold voltages of the dummy transistor of a memory string in the memory string group Gr63, so that string resistances corresponding to the memory string group Gr0, . . . , and the memory string group Gr63 decrease sequentially. Here, the dummy transistor includes a bottom dummy transistor and/or a top dummy transistor.

It can be understood that in an example of the present disclosure, by setting different threshold voltages of the dummy transistors of the memory strings in different memory string groups, a difference of the bit line voltage drops of the different memory strings can be compensated. Specifically, if the closer to the first end, the smaller the bit line voltage drop of a memory string within a memory string group is, the closer to the first end, the higher the threshold voltage of the dummy transistor of a memory string within a memory string group is; if the closer to the second end, the bigger the bit line voltage drop of a memory string within a memory string group is, the closer to the second end, the lower the threshold voltage of the dummy transistor of a memory string within a memory string group is.

In some examples, each of the memory string groups includes a plurality of memory strings, and each of the memory strings includes a dummy transistor; wherein the threshold voltages of the dummy transistors of each of the memory strings within a same memory string group are substantially the same. The scheme that the threshold voltages of the dummy transistors of each of the memory strings within the same memory string group are substantially the same is similar to the scheme in the above examples that the threshold voltages of the top select transistors of each of the memory strings within the same memory string group are substantially the same, details may be referred to the related description in the above examples, and details are not described herein again.

In some examples, each of the memory string groups includes a plurality of memory strings, and each of the memory strings includes a dummy transistor; wherein along the direction from the first end towards the second end, the threshold voltages of the dummy transistors of the plurality of memory strings within the same memory string group decrease sequentially. The scheme that the threshold voltages of the dummy transistors of the plurality of memory strings within the same memory string group decrease sequentially is similar to the scheme in the foregoing examples that the threshold voltages of the top select transistors of each of the memory strings within the same memory string group decrease sequentially, and the details may be referred to the related descriptions in the foregoing examples, and details are not described herein again.

In some examples, the string resistances corresponding to a plurality of memory string groups with which a same selected bit line of the plurality of bit lines is coupled decrease sequentially along a direction from a first end of the selected bit line towards a second end of the selected bit line, includes: along the direction from the first end towards the second end, the threshold voltages of the top select transistors of the plurality of memory string groups with which the same selected bit line is coupled decrease sequentially, and the threshold voltages of the dummy transistors of the plurality of memory string groups with which the same selected bit line is coupled decrease sequentially.

It can be understood that in an example of the present disclosure, by setting different threshold voltages of the top select transistors and different threshold voltages of the dummy transistors of the memory strings within different memory string groups, a difference of bit line voltage drops of the different memory strings can be further compensated. The change rule of the threshold voltages of the top select transistors and the change rule of the threshold voltages of the dummy transistors of the memory strings within different memory string groups may be referred to the related descriptions in the foregoing examples, and details are not described herein again.

In some examples, among the first memory string and the second memory string coupled with the same selected bit line of the plurality of bit lines, along the direction from the first end of the selected bit line towards the second end of the selected bit line, the string resistance of the first memory string is bigger than the string resistance of the second memory string, includes: among the first memory string and the second memory string coupled with the same bit line, along the direction from the first end towards the second end, the threshold voltage of the dummy transistor of the first memory string is bigger than the threshold voltage of the dummy transistor of the second memory string. In this way, the string resistance of the first memory string may be greater than the string resistance of the second memory string.

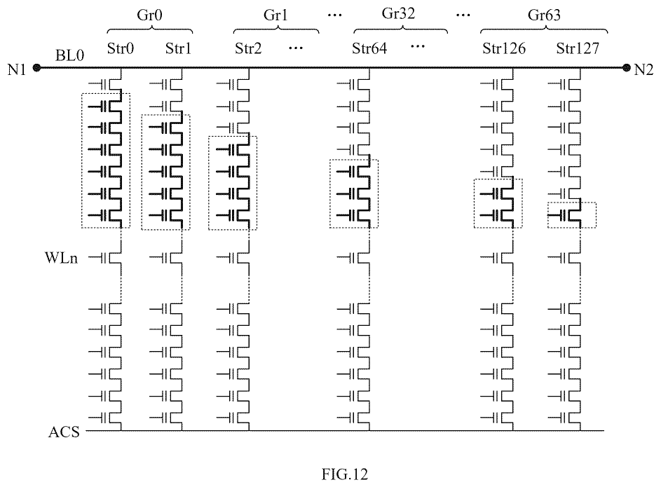

FIG. 12 is a schematic diagram of one bit line being coupled with a plurality of memory strings shown according to a second example of the present disclosure. For ease of understanding, the selected bit line is BL0 that is coupled with 64 memory string groups and each of the memory string groups includes 2 memory strings will be taken as an example for illustration. The details about BL0 being coupled with 64 memory string groups and each of the memory string groups includes 2 memory strings may be referred to the related description of FIG. 8.

In some examples, the string resistances corresponding to the plurality of memory string groups with which the same selected bit line of the plurality of bit lines is coupled decrease sequentially along the direction from the first end of the selected bit line towards the second end of the selected bit line, includes: along the direction from the first end towards the second end, the number of the dummy transistors of the plurality of memory string groups with which the same selected bit line is coupled decrease sequentially.

For example, in combination with FIG. 12, along the direction from the first end N1 towards the second end N2, the number of the dummy transistors of the memory string group Gr0, the memory string group Gr1, . . . , the memory string group Gr32, . . . , and the memory string group Gr63 with which the BL0 is coupled decrease sequentially, for example, the number of the dummy transistors of memory strings in the memory string group Gr0>, . . . , >the number of the dummy transistors of memory strings in the memory string group Gr63, so that string resistances corresponding to the memory string group Gr0, the memory string group Gr1, . . . , and the memory string group Gr63 decrease sequentially.

It may be understood that in an example of the present disclosure, by setting different numbers of dummy transistors of the memory strings within the different memory string groups, variable resistors may be constructed to compensate for differences in bit line voltage drops of different memory strings. Specifically, if the closer to the first end, the smaller the bit line voltage drop of the memory string within the memory string group is, the closer to the first end, the bigger the number of the dummy transistors of the memory string within the memory string group is; if the closer to the second end, the bigger the bit line voltage drop of the memory string within the memory string group is, the closer to the second end, the smaller the number of the dummy transistors of the memory string in the memory string group is.

In some examples, the string resistances corresponding to the plurality of memory string groups with which the same selected bit line of the plurality of bit lines is coupled decrease sequentially along a direction from the first end of the selected bit line towards the second end of the selected bit line, includes: along the direction from the first end towards the second end, the threshold voltages of the top select transistors of the plurality of memory string groups with which the same selected bit line is coupled decrease sequentially, and the number of the dummy transistors of the plurality of memory string groups with which the same selected bit line is coupled decrease sequentially.

It can be understood that in an example of the present disclosure, by setting different threshold voltages of the top select transistors and different number of the dummy transistors of the memory strings within different memory string groups, the difference of the bit line voltage drops of the different memory strings can be further compensated. The change rule of the threshold voltages of the top select transistors of the memory strings in different memory string groups and the change rule of the number of the dummy transistors may be referred to the related description in the foregoing examples, and details are not described herein again.

In some examples, each of the memory string groups includes a plurality of memory strings, and each of the memory strings includes a dummy transistor; wherein the number of dummy transistors of each of the memory strings within the same memory string group is the same.

For example, as shown in FIG. 12, within the memory string group Gr0, the number of the dummy transistors of the memory string Str0 and the number of the dummy transistors of the memory string Str1 may be the same; and the number of the dummy transistors of the memory string Str1 is greater than the number of the dummy transistors of the memory string Str2. Within the memory string group Gr63, the number of the dummy transistors of the memory string Str126 and the number of the dummy transistors of the memory string Str127 may be the same; and the number of the dummy transistors of the memory string Str125 is greater than the number of the dummy transistors of the memory string Str126.

It can be understood that, in an example of the present disclosure, the plurality of memory strings coupled with the same selected bit line are divided into the plurality of memory string groups, and the number of the dummy transistors of each of the memory strings within the same memory string group are substantially the same, so that reasonable compensation may be performed according to the degree of the bit line voltage drop of the plurality of memory strings. For example, the memory strings with substantially the same degree of the bit line voltage drop are grouped together into one group, and the number of the dummy transistors of the memory strings that are grouped into one group are the same. Here, the grouping manner of the plurality of memory strings is not limited to that shown in FIG. 12.

In some other examples, each of the memory string groups includes a plurality of memory strings, and each of the memory strings includes a dummy transistor; and wherein along the direction from the first end towards the second end, the number of the dummy transistors of the plurality of memory strings within the same memory string group decrease sequentially.

For example, referring to FIG. 12, within the memory string group Gr0, the number of the dummy transistors of the memory string Str0 is greater than the number of the dummy transistors of the memory string Str1. Within the memory string group Gr63, the number of the dummy transistors of the memory string Str126 is greater than the number of the dummy transistors of the memory string Str127. For example, in this example, the number M of the dummy transistors of the 128 memory strings Str0 to Str127 coupled with BL0 satisfies the following rule: Mₛₜᵣ₀>Mₛₜᵣ₁>Mₛₜᵣ₂> . . . >Mₛₜᵣ₁₂₆>Mₛₜᵣ₁₂₇. For ease of understanding, the dummy transistor of each of the memory strings in FIG. 12 is boxed with dotted lines, and the dummy transistor of each of the memory strings is showed in bold.

It can be understood that in an example of the present disclosure, along the direction from the first end towards the second end, the number of the dummy transistors of the plurality of memory strings coupled with the same selected bit line decrease sequentially, thereby compensating for a difference of the bit line voltage drop of different memory strings. Specifically, if the closer to the first end, the smaller the bit line voltage drop of the memory string is, the closer to the first end, the greater the number of the dummy transistors of the memory string is; if the closer to the second end, the greater the bit line voltage drop of the memory string is, the closer to the second end, the smaller the number of the dummy transistors of the memory string is.

It should be noted that, before the semiconductor device leaves the factory, a part of transistors located between the top select transistor and the bottom select transistor in each of the memory strings may be configured as dummy transistors which are not configured to store data, and the other part of transistors between the top select transistor and the bottom select transistor are memory cells that are configured to store data.

In some examples, a memory string includes at least two sub-memory strings stacked in sequence; wherein a dummy transistor is a transistor at the bottom of at least one sub-memory string. In practical applications, in order to integrate more memory cells in the same substrate area, the number of layers of the three-dimensional NAND memory stack can be increased. Considering the difficulty of deep hole etching and the yield of the device, at least two sub-stacks and a channel structure extending through the at least two sub-stacks may be formed step by step, thereby forming the at least two sub-memory strings stacked in sequence, and a dummy transistor may be a transistor at the bottom of the at least one sub-memory string. It may also be understood that, the gate layer located at the bottom of the at least one sub-stack is configured as a dummy word line, and the transistor coupled with the dummy word line in the memory string is the dummy transistor.

In some examples, along the direction from the first end of the selected bit line towards the second end of the selected bit line, among the first memory string and the second memory string coupled with the same selected bit line of the plurality of bit lines, the string resistance of the first memory string is greater than the string resistance of the second memory string, includes: along the direction from the first end towards the second end, among the first memory string and the second memory string coupled with the same selected bit line, the number of the dummy transistors of the first memory is greater than the number of the dummy transistors of the second memory. In this way, the string resistance of the first memory string may be greater than the string resistance of the second memory string.

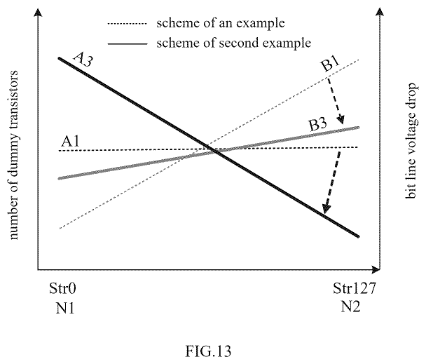

FIG. 13 is a second schematic diagram of bit line voltage drops shown according to various examples shown in the present disclosure. A dotted line in FIG. 13 represents an example, wherein the dotted line A1 represents that the number of the dummy transistors of the 128 memory strings Str0 to Str127 coupled with the same selected bit line are the same, and the dotted line B1 represents the change rule of the bit line voltage drops of the 128 memory strings coupled with the same selected bit line; a solid line in FIG. 13 represents a second example, wherein the solid line A3 represents that the number of the dummy transistors of the 128 memory strings Str0 to Str127 coupled with the same selected bit line decrease sequentially, and the solid line B3 represents the change rule of the bit line voltage drops of the 128 memory strings coupled with the same selected bit line. It can be seen from FIG. 13 that, by setting the number of the dummy transistors of the 128 memory strings Str0 to Str127 coupled with the same selected bit line to decrease sequentially, a difference of the bit line voltage drops of different memory strings can be compensated, as shown by the dotted line B1 to the solid line B3 in FIG. 13. Here, the details of the second example may be referred to the example related to FIG. 12, and the details are not described herein again for brevity.

In some examples, a memory string includes a plurality of memory cells connected in series; the semiconductor device further includes a plurality of word lines and a peripheral circuit, each of the word lines is coupled with a plurality of memory cells arranged along a second direction; the second direction intersects with the first direction; the peripheral circuit is coupled with the plurality of memory string groups through the plurality of word lines and the plurality of bit lines, and the peripheral circuit is configured to: apply a read voltage and a pass voltage to a selected word line and an unselected word line of the plurality of word lines respectively; apply corresponding input voltages to a plurality of top select lines coupled with the plurality of memory string groups, respectively; and sense an electrical signal on the selected bit line, wherein string currents corresponding to the plurality of memory string groups with which the same selected bit line is coupled increase sequentially in a direction from the first end towards the second end. The word lines and peripheral circuits may be referred to the related descriptions of FIG. 1, FIG. 3, and FIG. 4. Here, the electrical signal includes a current signal and/or a voltage signal, and in this example, the electrical signal being a current signal is taken as an example for illustration.

For example, referring to FIG. 8, when an computation is being performed, the input voltages obtained by converting the input data are applied to the gates of the corresponding top select transistors (for example, the input voltages Vᵢₙ₀, . . . , Vᵢₙ₁₂₇ are applied to the gates of the top select transistors TSG0, . . . , TSL127, respectively), and a read voltage Vᵣd is applied to the selected word line and a pass voltage Vₚₐₛₛ is applied to the unselected word lines; and the computation result can be obtained by sensing the current on the bit line and converting the current on the bit line. Here, since the string resistances corresponding to the memory string group Gr0 to the memory string group Gr64 decrease sequentially, the string currents corresponding to the memory string group Gr0 to the memory string group Gr64 increase sequentially, for example, the string currents corresponding to the plurality of memory string groups with which the same selected bit line is coupled increase sequentially.

In some examples, the semiconductor device includes the plurality of memory blocks each including the plurality of memory string groups. It can be understood that, the threshold voltages of the top select transistors and/or the threshold voltages of the dummy transistors and/or the number of the dummy transistors of the plurality of memory string groups with which the same bit line is coupled in each of the memory blocks may adopt the schemes in the above examples, thereby reducing the influence of the bit line voltage drop on each of the memory blocks, especially in the case that parallel calculation is performed by using a plurality of memory blocks to improve the computational power of the semiconductor device. The memory block may be referred to the related descriptions of FIG. 2.

In some examples, the semiconductor device includes a plurality of memory planes each including a plurality of memory blocks. It can be understood that, the threshold voltages of the top select transistors and/or the threshold voltages of the dummy transistors and/or the number of the dummy transistors of the plurality of memory string groups with which the same bit line is coupled in each of the memory blocks may adopt the schemes in the above examples, thereby reducing the influence of the bit line voltage drop on each of the memory blocks, especially in the case that parallel calculation is performed by using a plurality of memory planes to further improve the computational power of the semiconductor device. The memory block may be referred to the related descriptions of FIG. 2.

Based on the above semiconductor devices, the present disclosure provides an operating method of a semiconductor device. The operating method may be applied to the semiconductor device in any of the above examples. For example, the operating method may be used for the semiconductor device to perform computations, and a memory cell array of the semiconductor device is configured to store a weight matrix.

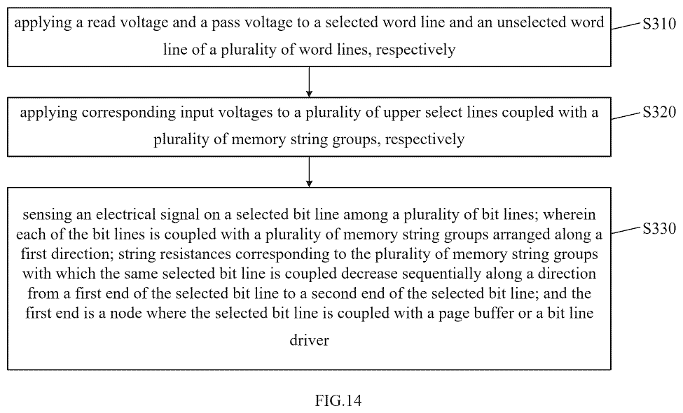

FIG. 14 is a flowchart of an operating method of a semiconductor device shown according to an example of the present disclosure. It should be noted that the steps shown in FIG. 14 are not exclusive, and other steps may be performed before, after, or between any steps in the operations shown; the order of the steps shown in FIG. 14 may be adjusted according to actual requirements. Referring to FIG. 14, the operating method includes the following steps:

Step S310: applying a read voltage and a pass voltage to a selected word line and an unselected word line of a plurality of word lines, respectively.

Step S320: applying corresponding input voltages to a plurality of upper select lines coupled with a plurality of memory string groups, respectively.

Step S330: sensing an electrical signal on the selected bit line among the plurality of bit lines; wherein each of the bit lines is coupled with a plurality of memory string groups arranged along a first direction; string resistances corresponding to the plurality of memory string groups with which the same selected bit line is coupled decrease sequentially along a direction from a first end of the selected bit line towards a second end of the selected bit line; and the first end is a node where the selected bit line is coupled with a page buffer or a bit line driver.

For example, before a computation is performed by using the semiconductor device, a plurality of weights of a weight matrix may be respectively written into a plurality of memory cells coupled with the selected word line; and when the computation is performed by using the semiconductor device, a read voltage V_{rd} and a pass voltage Vₚₐₛₛ are respectively applied to the selected word line and the unselected word line in the plurality of word lines, and an input voltage obtained by converting input data is applied to a corresponding top select line (for example, input voltages Vᵢₙ₀, . . . , Vᵢₙ₁₂₇ are respectively applied to 128 top select lines coupled with the top select transistors TSG0 to TSG127), and a current I_{D0} on the selected bit line BL0 is sensed, as shown in FIG. 8. Here, there may be one or more selected bit lines.

In some examples, the foregoing operating method further includes: performing a program operation on the top select transistors of the plurality of memory string groups, so that threshold voltages of the top select transistors of the plurality of memory string groups with which the same selected bit line is coupled decrease sequentially along a direction from the first end towards the second end.

In an example of the present disclosure, before the semiconductor device leaves the factory, the threshold voltages of the top select transistors of the plurality of memory string groups with which the same bit line is coupled may be programmed to decrease sequentially along the direction from the near end of the bit line to the far end of the bit line, so that when the semiconductor device is configured to perform a computation, the string resistances corresponding to the plurality of memory string groups with which the same bit line is coupled may decrease sequentially to compensate for a difference of a bit line voltage drop between different memory strings. In practical applications, the program operation may be performed in a trimming phase before the semiconductor device leaves the factory.

In some examples, in the process of performing the program operation, the program pulse width of the top select transistors of the plurality of memory string groups relatively close to the first end is greater than the program pulse width of the top select transistors of the plurality of memory string groups relatively far away from the first end.

In an example of the present disclosure, the program pulse width of the top select transistors of the plurality of memory string groups in the program operation can be controlled such that the threshold voltages of the top select transistors of the plurality of memory string groups with which the same selected bit line is coupled decrease sequentially along the direction from the near end of the bit line to the far end of the bit line. Specifically, the program pulse width of the top select transistor near to the near end of the bit line is greater than the program pulse width of the top select transistor near to the far end of the bit line.

In some examples, in the process of performing the program operation, a program time of the top select transistors of the plurality of memory string groups relatively close to the first end is greater than a program time of the top select transistors of the plurality of memory string groups relatively far away from the first end.

In an example of the present disclosure, the program time of the top select transistors of the plurality of memory string groups in the program operation can be controlled such that the threshold voltages of the top select transistors of the plurality of memory string groups with which the same selected bit line is coupled decrease sequentially along the direction from the near end of the bit line to the far end of the bit line. Specifically, the program time of the top select transistor near the near end of the bit line is greater than the program time of the top select transistor near the far end of the bit line.

Of course, in other examples, the program pulse width and the program time may be controlled at the same time, so that the threshold voltages of the top select transistors of the plurality of memory string groups with which the same selected bit line is coupled decrease sequentially along the direction from the near end of the bit line to the far end of the bit line. Specifically, the program pulse width of the top select transistor near the near end of the bit line is greater than the program pulse width of the top select transistor near the far end of the bit line, and the program time of the top select transistor near the near end of the bit line is greater than the program time of the top select transistor near the far end of the bit line.

In some examples, the foregoing operating method further includes: performing a program operation on the dummy transistors of the plurality of memory string groups, so that the threshold voltages of the dummy transistors of the plurality of memory string groups with which the same selected bit line is coupled decrease sequentially along the direction from the first end towards the second end.

In an example of the present disclosure, before the semiconductor device leaves the factory, the threshold voltages of the dummy transistors of the plurality of memory string groups with which the same bit line is coupled may be programmed to decrease sequentially along the direction from the near end of the bit line to the far end of the bit line, so that when the semiconductor device is configured to perform a computation, the string resistances corresponding to the plurality of memory string groups with which the same bit line is coupled may decrease sequentially to compensate for a difference of a bit line voltage drop between different memory strings. In practical applications, the program operation may be performed in a trimming phase before the semiconductor device leaves the factory.

In some examples, the foregoing operating method further includes: applying a pass voltage to a dummy word line coupled with the dummy transistors; wherein along the direction from the first end towards the second end, the number of the dummy transistors of the plurality of memory string groups with which the same selected bit line is coupled decrease sequentially. In an example of the present disclosure, when a computation is performed by using the semiconductor device, a pass voltage Vₚₐₛₛ is applied to the dummy word line, so that the dummy transistors coupled with the dummy word line are turned on.

Based on the foregoing semiconductor device, an example of the present disclosure provides a system, including: at least one semiconductor device in any one of the foregoing examples; and a controller coupled with the semiconductor device, wherein the controller is configured to send input data to the semiconductor device and receive a computation result of the semiconductor device.

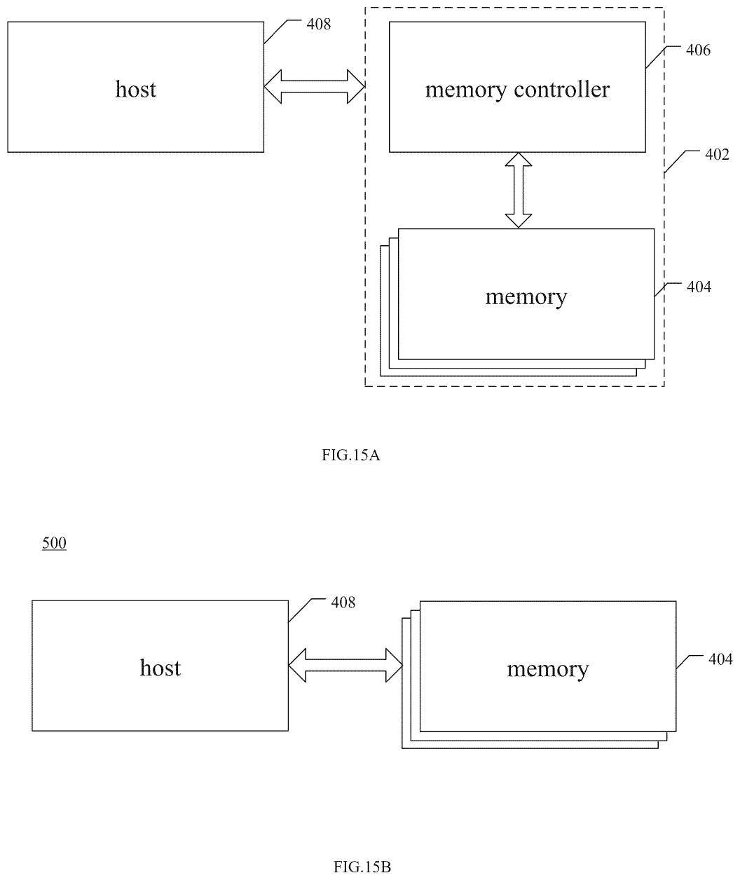

In some examples, the system in the foregoing examples may be the memory system 402 shown in FIG. 15A, the memory system 402 includes a memory controller 406 and a memory 404 coupled with the memory controller 406, the memory controller 406 may include a graphics processing unit (GPU), the memory 404 may include the semiconductor device 200 in the foregoing examples, and the GPU in the memory controller 406 may control the memory 404 to perform parallel computing.

According to some examples, as shown in FIG. 15A, the memory controller 406 is coupled to the memory 404 and the host 408 and configured to control operations of the memory 404, such as read, erase, program, compute operations. The memory controller 406 may manage data stored in the memory 404 and communicate with the host 408.

In some other examples, the system in the foregoing examples may be the system 500 shown in FIG. 15B, the system 500 includes a host 408 and a memory 404 coupled with the host 408, the host 408 may include a GPU, the memory 404 may include the semiconductor device 200 in the foregoing examples, and the GPU in the host 408 may control the memory 404 to perform parallel computing.

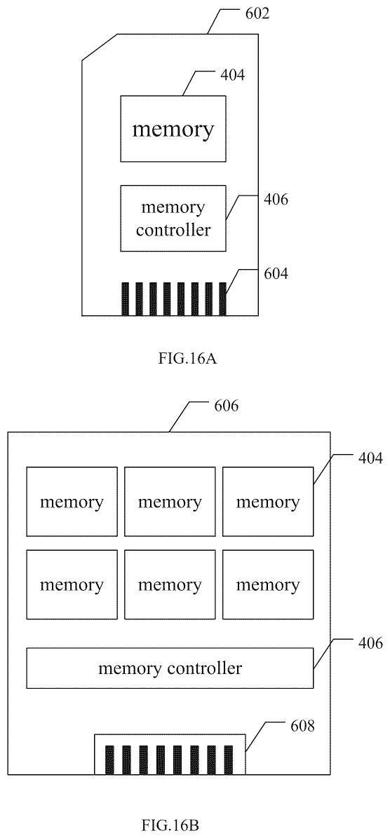

In one example shown in FIG. 16A, the system may be integrated into the memory card 602, the semiconductor device in the system may be the memory 404 in the memory card 602, and the controller in the system may be the memory controller 406 in the memory card 602. The memory card 602 may be one of a compact flash memory card, a smart media card (SMC), a memory stick (MS), a multi-media card (MMC) (such as an RS-MMC, an MMCmicro, an eMMC, or the like), a secure digital card (such as a MiniSD card, a Micro SD card, an SDHC card, or the like), or a universal flash memory card. The memory card 602 may also include a memory card connector 604 that couples the memory card 602 with a host. In another example shown in FIG. 16B, the system may be integrated into a solid state disk (SSD) 606, the semiconductor device in the system may be the memory 404 in the SSD 606, and the controller in the system may be the memory controller 406 in the SSD 606. The solid state drive 606 may further include a solid state drive connector 608 that couples the solid state drive 606 with the host-side device. In some implementations, the storage capacity and/or operating speed of the solid state drive 606 is greater than the storage capacity and/or operating speed of the memory card 602.

In some other examples, the system may be integrated into terminal equipment, and the controller may be a central processing unit (CPU) of the terminal equipment, here, the terminal equipment may include, but is not limited to, any terminal equipment or portable terminal equipment such as a mobile phone, a smart television, a smart speaker, wearable equipment, a tablet computer, a desktop computer, an all-in-one computer, a handheld computer, a notebook computer, a server, an ultra-mobile personal computer (UMPC), a netbook, a personal digital assistant (PDA), a laptop computer (laptop), a mobile computer, an augmented reality (AR) device, a virtual reality (VR) device, and an artificial intelligence (AI) device.

In some examples, the system may be configured to implement various complex algorithms and data processing tasks. In a specific example, the system may be used in the field of artificial intelligence, such as machine learning, deep learning, neural networks, convolutional neural networks, and the like.

The features disclosed in the several equipment examples provided by the present disclosure may be arbitrarily combined without conflict to obtain a new equipment example.

The methods disclosed in the several method examples provided by the present disclosure may be arbitrarily combined without conflict to obtain new method examples.

Reference throughout the specification to “one example” or “an example” means that a particular feature, structure, or characteristic related to the example is included in at least one example of the present disclosure. Thus, the “in one example” or “in an example” throughout this specification does not necessarily refer to the same example. Furthermore, these particular features, structures, or characteristics may be combined in any suitable manner in one or more examples. In various examples of the present disclosure, the sizes of the sequence numbers of each process do not mean an execution sequence, and the execution sequence of each process should be determined according to its function and internal logic, and the implementation process of the examples of the present disclosure should not be limited. The sequence numbers of the examples of the present disclosure are merely for description, and do not represent the advantages and disadvantages of the examples.

It should be noted that, in this document, the terms “include”, “comprise”, or any other variation thereof are intended to cover a non-exclusive inclusion, so that a process, method, article, or device including a series of elements includes not only those elements, but also other elements not explicitly listed, or elements inherent to such a process, method, article, or device. Without more limitations, an element defined by the statement “including one” does not preclude the presence of another identical element in a process, method, article, or apparatus that includes the element.

The above description includes implementations of the present disclosure, but the protection scope of the present disclosure is not limited thereto, and changes or substitutions that any person skilled in the art may easily conceive of within the technical scope of the present disclosure should be covered within the protection scope of the present disclosure.

What is claimed is:

1. A semiconductor device, comprising:
a plurality of memory string groups each comprising at least one memory string; and
a plurality of bit lines each coupled with the plurality of memory string groups arranged along a first direction, wherein string resistances corresponding to the plurality of memory string groups with which a same selected bit line of the plurality of bit lines is coupled decrease sequentially along a direction from a first end of the selected bit line towards a second end of the selected bit line, and wherein the first end is a node where the selected bit line is coupled with a page buffer or a bit line driver.

2. The semiconductor device of claim 1, wherein the string resistances corresponding to the plurality of memory string groups with which the same selected bit line of the plurality of bit lines is coupled decrease sequentially along the direction from the first end of the selected bit line towards the second end of the selected bit line comprises:
along the direction from the first end towards the second end, threshold voltages of top select transistors of the plurality of memory string groups with which the same selected bit line is coupled decrease sequentially.

3. The semiconductor device of claim 2, wherein each of the memory string groups comprises a plurality of the memory strings, and each of the memory strings comprises a top select transistor; and wherein threshold voltages of the top select transistors of each of the memory strings within a same memory string group are substantially the same.

4. The semiconductor device of claim 2, wherein each of the memory string groups comprises a plurality of the memory strings, and each of the memory strings comprises the top select transistor; and wherein along the direction from the first end towards the second end, the threshold voltages of the top select transistors of a plurality of the memory strings within the same memory string group decrease sequentially.

5. The semiconductor device of claim 1, wherein the string resistances corresponding to the plurality of memory string groups with which the same selected bit line of the plurality of bit lines is coupled decrease sequentially along the direction from the first end of the selected bit line towards the second end of the selected bit line comprises:
along the direction from the first end towards the second end, threshold voltages of dummy transistors of the plurality of memory string groups coupled with which the same selected bit line is coupled decrease sequentially.

6. The semiconductor device of claim 1, wherein the string resistances corresponding to the plurality of memory string groups with which the same selected bit line of the plurality of bit lines is coupled decrease sequentially along the direction from the first end of the selected bit line towards the second end of the selected bit line comprises:
along the direction from the first end towards the second end, a number of dummy transistors of the plurality of memory string groups with which the same selected bit line is coupled decreases sequentially.

7. The semiconductor device of claim 6, wherein each of the memory string groups comprises a plurality of memory strings, and each of the memory strings comprises the dummy transistors; and wherein the number of the dummy transistors of each of the memory strings within the same memory string group is the same.

8. The semiconductor device of claim 6, wherein each of the memory string groups comprises a plurality of memory strings, and each of the memory strings comprises the dummy transistors; and wherein along the direction from the first end towards the second end, the number of the dummy transistors of a plurality of the memory strings within the same memory string group decrease sequentially.

9. The semiconductor device of claim 7, wherein the memory string comprises at least two sub-memory strings stacked in sequence; and wherein the dummy transistor is a transistor at a bottom of at least one sub-memory string.

10. The semiconductor device of claim 1, wherein the memory string comprises a plurality of memory cells connected in series; the semiconductor device further comprises a plurality of word lines and a peripheral circuit, each of the word lines is coupled with the plurality of memory cells arranged along a second direction, and the second direction intersects with the first direction;
the peripheral circuit is coupled with the plurality of memory string groups through the plurality of word lines and the plurality of bit lines, and the peripheral circuit is configured to:
apply a read voltage and a pass voltage to a selected word line and an unselected word line of the plurality of word lines, respectively;
apply corresponding input voltages to a plurality of top select lines coupled with the plurality of memory string groups, respectively; and
sense an electrical signal on the selected bit line; wherein along the direction from the first end towards the second end, string currents corresponding to the plurality of memory string groups with which the same selected bit line is coupled increase sequentially.

11. The semiconductor device of claim 1, wherein the semiconductor device comprises a plurality of memory blocks, and each of the memory blocks comprises the plurality of memory string groups.

12. The semiconductor device of claim 11, wherein the semiconductor device comprises a plurality of memory planes, and each of the memory planes comprises the plurality of the memory blocks.

13. The semiconductor device of claim 1, wherein the semiconductor device comprises a three-dimensional NAND memory.

14. An operating method of a semiconductor device, comprising:
applying a read voltage and a pass voltage to a selected word line and an unselected word lines of a plurality of word lines, respectively;
applying corresponding input voltages to a plurality of upper select lines coupled with a plurality of memory string groups, respectively; and
sensing an electrical signal on a selected bit line among a plurality of bit lines, wherein each of the bit lines is coupled with the plurality of memory string groups arranged along a first direction; string resistances corresponding to the plurality of memory string groups with which the same selected bit line is coupled decrease sequentially along a direction from a first end of the selected bit line towards a second end of the selected bit line, and wherein the first end is a node where the selected bit line is coupled with a page buffer or a bit line driver.

15. The operating method of claim 14, further comprising:
performing a program operation on top select transistors of the plurality of memory string groups, so that threshold voltages of the top select transistors of the plurality of memory string groups with which the same selected bit line is coupled decrease sequentially along the direction from the first end towards the second end.

16. The operating method of claim 15, wherein in a process of performing the program operation, a program pulse width of the top select transistors of the plurality of memory string groups relatively close to the first end is greater than a program pulse width of the top select transistors of the plurality of memory string groups relatively far away from the first end.

17. The operating method of claim 15, wherein in a process of performing the program operation, a program time of the top select transistors of the plurality of memory string groups relatively close to the first end is greater than a program time of the top select transistors of the plurality of memory string groups relatively far away from the first end.

18. The operating method of claim 14, further comprising:
performing a program operation on dummy transistors of the plurality of memory string groups, so that threshold voltages of the dummy transistors of the plurality of memory string groups with which the same selected bit line is coupled decrease sequentially along the direction from the first end towards the second end.

19. The operating method of claim 14, further comprising:
applying the pass voltage to a dummy word line coupled with a dummy transistor; wherein along the direction from the first end towards the second end, a number of dummy transistors of the plurality of memory string groups with which the same selected bit line is coupled decreases sequentially.

20. A system, comprising:
at least one semiconductor device, comprising:
a plurality of memory string groups each comprising at least one memory string; and
a plurality of bit lines each coupled with the plurality of memory string groups arranged along a first direction, wherein string resistances corresponding to the plurality of memory string groups with which a same selected bit line of the plurality of bit lines is coupled decrease sequentially along a direction from a first end of the selected bit line towards a second end of the selected bit line, and wherein the first end is a node where the selected bit line is coupled with a page buffer or a bit line driver; and
a controller coupled with the semiconductor device, wherein the controller is configured to send input data to the semiconductor device and receive a computation result of the semiconductor device.
